(19) United States
(12) Patent Application Publication
(10) Pub. No.: US 2017/0063381 A1
(43) Pub. Date: Mar. 2, 2017

(54) OSCILLATOR PROTECTION

(71) Applicant: Higher Ground LLC, Palo Alto, CA (US)

(72) Inventor: Robert S. REIS, Palo Alto, CA (US)

(21) Appl. No.: 15/247,177

(22) Filed: Aug. 25, 2016

Related U.S. Application Data
(63) Continuation-in-part of application No. 14/839,100, filed on Aug. 28, 2015, now abandoned.

(51) Int. Cl. H03L 1/04

(52) U.S. Cl. CPC H03L 1/04

(57) ABSTRACT

An oscillator may be embedded in a sealed hole in a circuit board, for the purpose of shielding it from air currents, including convective air currents. The hole may be formed by drilling. The oscillator may be mounted in the hole and may be covered by a heat-insulating material, for example, insulating tape.

### CROSS-REFERENCE TO RELATED APPLICATION

The present application is a continuation-in-part of U.S. patent application Ser. No. 14/839,100, filed on Aug. 28, 2015, and incorporated by reference herein.

### FIELD OF ENDEAVOR

Aspects of the present disclosure may relate to techniques for protecting oscillators, and more particularly, oscillators in circuits, such as, but not limited to, communication circuits.

### BACKGROUND

Oscillators are an important part of many electronic circuits. Oscillators may typically be used to generate waveforms, e.g., but not limited to, sinusoidal waveforms. In communication circuits, for example, oscillators may be used to generate one or more waveforms (e.g., carrier signal, sinusoidal waveforms for up-conversion and/or down-conversion, etc.). It may often be advantageous for the phase of the oscillator output to be as stable as possible.

One issue that may arise is that of stability in adverse conditions. Such conditions may often be metrological, but may also relate to such conditions as motion, shock, etc. Temperature may also play a role, and it may be advantageous to keep the temperature surrounding the oscillator as stable as possible.

One factor that may interfere with temperature stability around an oscillator may be the presence of air currents. Therefore, it may be desirable to protect an oscillator from air currents that may make the oscillator output less stable in phase.

Vonbun et al. (U.S. Pat. No. 3,071,736) teaches a method for stabilizing oscillator frequency by attaching the oscillator to a constant-temperature heat source. This is achieved by attaching the crystal via a conductive heat sink and a heat-conductive cavity to a body of a person. This is done by placing the crystal in a cavity (pocket) made out of heat conducting materials, keeping one side of the heat conducting materials against the body of a person, and the other side against the crystal. The heat conducting materials used in Vonbun et al. include silver and copper. Consequently, the heat sink of Vonbun et al. is both complicated and costly to manufacture.

In Fujii et al. (U.S. Pat. No. 6,163,688), an oscillator is encapsulated within a hermetically sealed case that is mounted beneath a circuit board. Fujii et al. focuses on fine tuning the characteristics of the oscillator by precisely controlling the positional relationship between the dielectric resonator and the circuit board with a precision of below 0.1 mm. Fujii et al. includes an adjustment mechanism operable to change a position of the dielectric resonator with respect to the circuit board. The background art noted in Fujii et al. describes that it was known to tune an oscillator by opening the cavity in which the oscillator resides and adjusting its position. In contrast, Fujii et al. teaches a method in which the cavity has adjusting screws that can simplify the tuning of oscillator characteristics by external screws without opening the cavity in which the oscillator resides. Fujii et al. is about fine tuning the frequency of an oscillator to be precisely at the desired frequency and requires a complicated method of manufacture, including the need for an additional casing to hold the oscillator.

In Okubo (U.S. Pat. No. 7,759,843), a piezoelectric resonator storage case includes a piezoelectric resonator stored therein, and a resonator container for storing a metal case. Here, the piezoelectric resonator includes: a piezoelectric resonator body having the metal case and a piezoelectric resonator element which is sealed in the metal case in an air tight manner. This invention is about providing “a piezoelectric resonator storage case, a heat source unit, a highly stable piezoelectric oscillator, and a method for manufacturing the highly stable piezoelectric oscillator, while minimizing a heat resistance between a metal case of the piezoelectric resonator and a heat source, without a thermally damaging a crystal resonator.” Okubo at col. 2, lines 11-17. As with the above-mentioned patents, Okubo relies on thermal coupling between the oscillator and accurate thermal sensing and controlling apparatus to thus achieve constant frequency by stabilizing the temperature of the oscillator. In particular, Okubo mounts a resonator on a printed circuit (PC) board that is fully enclosed in a heat-conductive (e.g., metal) container, with leads from the PC board to external circuitry. Okubo uses a power transistor as a stable/controlled heat source, which, according to Okubo, simplifies the structure of the heat source. Yet, this structure is still quite complicated, requires many steps to manufacture, requires a constant heat source, and is expensive to fabricate.

Huang et al. (U.S. Patent Application Publication No. 2009/0296361) “relates to a packaging structure of the integrated circuit module for covering the TXCO.” Huang et al. at paragraph 2. In contrast with the previously mentioned patents, this patent application is about isolating the oscillator and preventing it from exchanging heat with the environment. Huang et al. at paragraph 7. “TCXO is disposed inside a packaging structure so that the influence of environmental temperature different to the TCXO is decreasing and the performance of TCXO is optimized.” Huang et al. at paragraph 10. Huang et al. further states, “In other words, the heat of the TCXO 120 does not easily transfer to the environment and vice versa so that the temperature of the space containing the TCXO 120 maintains at a predetermined value.” Huang et al. at paragraph 21. Huang et al. further describes a hole used to further isolate the oscillator from the temperature of the environment, stating, “The second embodiment is shown in FIG. 4. In the second embodiment, the substrate 110 further comprises at least one hole 114.” Huang et al. at paragraph 26. However, Huang et al. further notes, “The hole 114 is defined under the TCXO 120.” Id. That is, Huang et al. uses the hole only for isolation. As a result, Huang et al. still requires an expensive metal casing to enclose an oscillator, on top of a thermosetting material, such as glue. Furthermore, Huang et al. discloses a crystal oscillator disposed on the top surface of the substrate with a hole positioned under the geometric center of the oscillator, meaning that the oscillator is not located in a hole, but rather on top of a hole, and that the oscillator requires further enclosure/heat protection, which adds expense the manufacturing process.

Dydyk et al. (U.S. Pat. No. 4,514,707) is entitled, “Dielectric Resonator Controlled Planar IMPATT Diode Oscillator.” This patent teaches that a “first tunable resonator controlling the fundamental frequency of the oscillator and a second tunable resonator controlling the second harmonic frequency of the oscillator are coupled to the first transmission line between the diode and the stabilizing load so that independent control of the fundamental and the second harmonic is attained in a temperature stable device.” Dydyk et al. at abstract. The system is manufactured with a hole below the oscillator circuit to facilitate tuning of the oscillator frequency. Dydyk et al. specifically states, “A tuner introduced from above the dielectric resonator is widely known to those skilled in the art and needs no further elaboration. A tuner may be introduced from below the dielectric resonator by means of a hole in the substrate and the ground plane through which the tuner can travel all the way to the dielectric resonator. The amount of tuner penetration is adjustable based upon need. With the tuner flush with the lower ground plane, the plane opposite the resonator, and the separation between the dielectric resonator and tuner increasing, negligible frequency tuning will be observed. The size of the through hole in the substrate is made smaller than the diameter of the dielectric resonator for the purposes of providing support for the dielectric resonator.” Dydyk et al. at col. 4, lines 18-31. That is, a hole, if one is made, is used to pass through a tuner, not to house an oscillator.

In Morino et al. (U.S. Pat. No. 5,661,441), the inventors present a “Dielectric Resonator Oscillator and Method of Manufacturing the Same.” Morino et al. at title. Morino et al. states, “A hole 36 in the substrate 34 allows the dielectric resonator 31 to contact case 37.” Morino et al. at col. 1, lines 19-20. However, the oscillator itself is enclosed in a metal case, and as such, the hole is not for the purpose of housing the oscillator but rather for the purpose of providing coupling between the resonating oscillator and the metal case. As part of the manufacturing process as described in FIG. 1, “A dielectric resonator 1 having cream solder 15 applied to its bottom 9 is mounted on the metal plate 6 through the hole 12 in the substrate 2.” Morino et al. at col. 2, lines It should be noted that the hole in Morino et al. is to facilitate heat transfer between the oscillator and the metal housing case. Also, the oscillator is substantially mounted above the substrate, and the hole is just used to thermally attach the oscillator to the metal case and is not used to house the oscillator.

Furuhata et al. (U.S. Pat. No. 8,405,283; also reproduced in Advances in Silicon Dioxide Research and Application: 2013 Edition) describes a manufacturing process in which “all or a part of the heat conduction path is formed by burying a material having a thermal conductivity higher than that of a flexural vibrator into a through hole that penetrates from the first region to the second region of flexible vibrator or through hole that penetrates in the vicinity of the first region and the second region.” Furuhata et al. at col. 5, lines 21-26. This hole requires heat conducting material to be inserted into the hole and is thus not merely a simple hole; consequently, the manufacturing process is more complex than simply forming a hole.

Saita (U.S. Pat. No. 8,334,639; also reproduced in Advances in Silicon Dioxide Research and Application: 2013 Edition) is entitled, “Package for Electronic Component, Piezoelectric Device and Manufacturing Method Thereof” Saita states, “The present invention relates to a package for an electronic component including an interior space in which the electronic component is airtightly sealed, a piezoelectric device airtightly sealing a piezoelectric resonator element serving as the electronic component, and a manufacturing method of the piezoelectric device.” Saita at col. 1, lines 8-13. Saita also states, “a package for an electronic component includes a first substrate and a second substrate. In the package, an interior space capable of housing the electronic component is formed between the first substrate and the second substrate, a sealing hole communicating with the interior space and an exterior is formed in at least one of the first substrate and the second substrate, the interior space can be airtightly sealed by melting a solid sealant provided in the sealing hole, and an interior wall of the sealing hole has a curved surface extending in directions of penetration and inner periphery of the sealing hole.” Saita at col. 2, lines 25-35. Saita continues, “When the electronic component is sealed by the package for an electronic component, the sphere sealant made of metal is often provided in the sealing hole and is melted so as to cover the sealing hole. According to the structure above, the interior wall of the sealing hole formed in at least one of the first substrate and the second substrate includes a curved surface extending in the directions of penetration and inner periphery of the sealing hole. Therefore, when the solid sealant is provided in the sealing hole, the portion where the surface of the sphere sealant contacts with or closes to the interior wall of the sealant can be widely ensured. Accordingly, when the sealant is melted for sealing the sealing hole, heat can be well conducted to the sealant through the interior wall surface of the sealing hole. Further, since the melted sealant easily wets and covers the interior wall surface of the sealing hole, sealing defects are suppressed. As a result, a piezoelectric device having stable oscillation characteristics and high reliability can be provided.” Saita at col. 2, lines 36-53. The sealing hole is formed in a “lid substrate” that covers a “resonator element substrate.” Saita at col. 5, lines 61-65. There is also a “base substrate” that is formed below the “resonator element substrate,” and the lid substrate and base substrate together contain a space in which the resonator substrate is enclosed. Saita at col. 5, line 65 to col. 6, line 15. The sealing hole is formed in the lid substrate and is described as “communicating with the interior space . . . and the exterior of the crystal resonator.” Saita at col. 7, lines 14-16. As further described in Saita, the sealing hole is formed with a specific and complex structure. Saita at col. 7, line 57 to col. 8, line 14 and FIGS. 4A-4B. The sealing hole also contains a “metal film” that “is formed of chrome and gold sequentially laminated by sputtering, vapor deposition, or the like, and nickel, palladium, and gold sequentially laminated on the gold laminated on the chrome by electroless plating.” Saita at col. 8, lines 32-36; see, also FIG. 4B, element 43. It is apparent from the above that the “sealing hole” of Saita: (a) does not contain the resonator structure; and (b) is complex and expensive to manufacture.

It may thus be desirable to provide a cost-effective solution to stabilize the phase of an oscillator without relying on an external constant temperature body. It may further be desirable to protect the oscillator from air currents that may make the oscillator output less stable in phase. Furthermore, it may be desirable to do so in such a way that manufacture is less complex and/or less expensive than in the above-discussed techniques for housing an oscillator.

### SUMMARY OF THE DISCLOSURE

Various aspects of the disclosure may be directed to methods and apparatus that may relate to the protection of oscillators from air currents. Such methods and apparatus may relate to various ways to physically shield an oscillator and to doing so in a way that reduces manufacturing costs in comparison to other methods of housing oscillators.

### BRIEF DESCRIPTION OF ACCOMPANYING DRAWINGS

Various aspects of this disclosure will now be discussed in further detail in conjunction with the attached drawings, in which:

FIGS. 1A and 1B show top and side/cross-sectional views (the latter through the line A-A shown in FIG. 1A), respectively, of an example according to an aspect of this disclosure;

FIGS. 2A, 2B and 2C show top and two side/cross-sectional views (the latter two through the line A-A shown in FIG. 2A), respectively, of examples according to an aspect of this disclosure;

FIGS. 3A and 3B show top and side/cross-sectional views (the latter through the line A-A shown in FIG. 3A), respectively, of an example according to an aspect of this disclosure;

FIGS. 4A and 4B show top and side/cross-sectional views (the latter through the line A-A shown in FIG. 4A), respectively, of an example according to an aspect of this disclosure; and

FIGS. 5A and 5B show top and side/cross-sectional views (the latter through the line A-A shown in FIG. 5A), respectively, of an example according to an aspect of this disclosure.

### DETAILED DESCRIPTION OF ASPECTS OF THE DISCLOSURE

Oscillators used in various circuits may take various forms but are often crystals or other timing elements. Such oscillators, e.g., crystal oscillators, may incorporate various controls. Examples of controlled crystal oscillators may include temperature-controlled crystal oscillators (TCXOs) and oven-controlled crystal oscillators (OCXOs), but are not limited thereto. The oscillators being considered in this disclosure are not limited to any particular type.

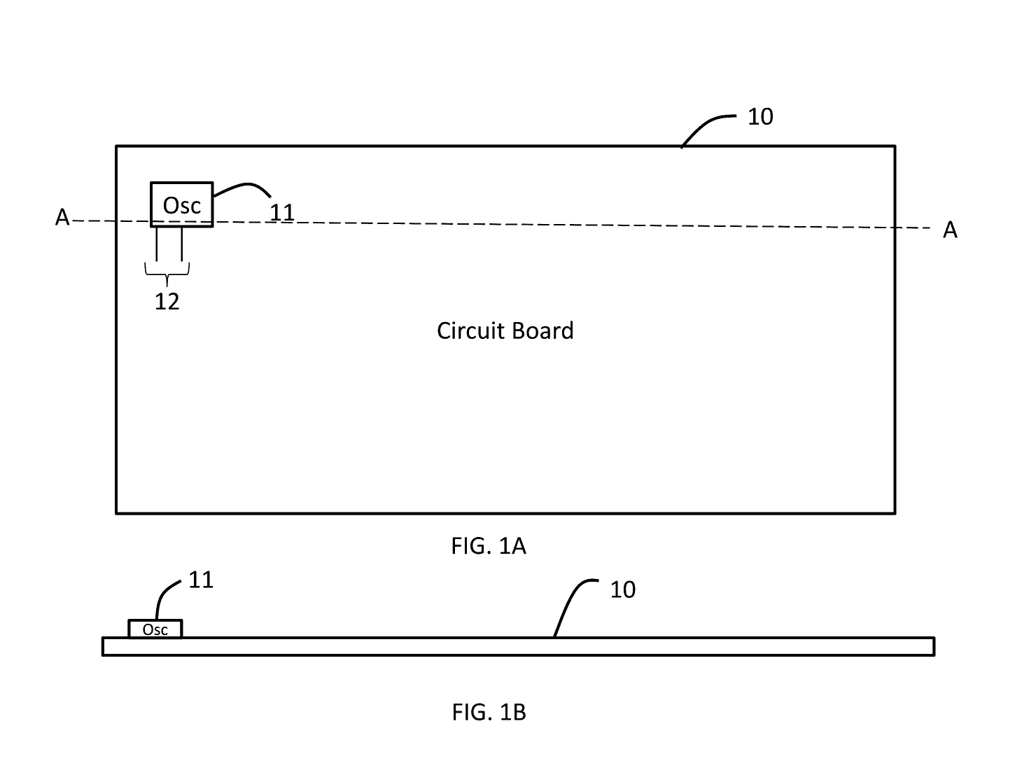

FIGS. 1A and 1B, show, respectively, top and side views of an example according to an aspect of this disclosure. In the example, an oscillator 11 is mounted on a circuit board 10. This example is not limiting, and the oscillator 11 may be mounted on or in other structures; this example is merely being used in FIGS. 1A and 1B to illustrate various aspects of this disclosure. The circuit board 10 does not explicitly show any other modules or circuitry, for the sake of simplicity in illustrating various aspects of this disclosure, but generally, other circuitry and/or modules may be present on circuit board 10. Circuit board 10 may typically be made of a non-heat-conducting material, such as, but not limited to, fiberglass, plastic, etc. Oscillator 11 may have leads/wires 12 that may be connected to other components, power, ground, etc.; two leads are shown, but the invention is not limited to an oscillator 11 having only two leads, and in general, oscillator 11 may have more than two leads. The leads 12 may be formed on the circuit board 10 and may connect to contacts on the oscillator 11.

In the scenario shown in FIGS. 1A and 1B, oscillator 11 is exposed and may be subjected to air currents. Such air currents may be naturally generated, generated by other components on the circuit board 10, generated by other components of a system containing oscillator 11 and/or circuit board 10, etc. A result of such air currents may be a differential heating and/or cooling of the oscillator, which may give rise to phase instability. However, these effects may be eliminated or minimized by protecting the oscillator 11 from such air currents.

The actual oscillator 11 may be contained in some package or chip that may, for example, enable simple mounting, or it may not have any packaging. In the ensuing discussion, when the “oscillator” is referred to, both of these scenarios are intended. That is, where the discussion refers to “covering” or “surrounding” or “embedding” (or similar) the oscillator, if the oscillator is already contained in some type of packaging, the intention is to “cover” or “surround” or “embed” (or similar) the entire oscillator package, and the packaging is not intended to be understood as corresponding to the “covering” or “surrounding” or “embedding” (or similar).

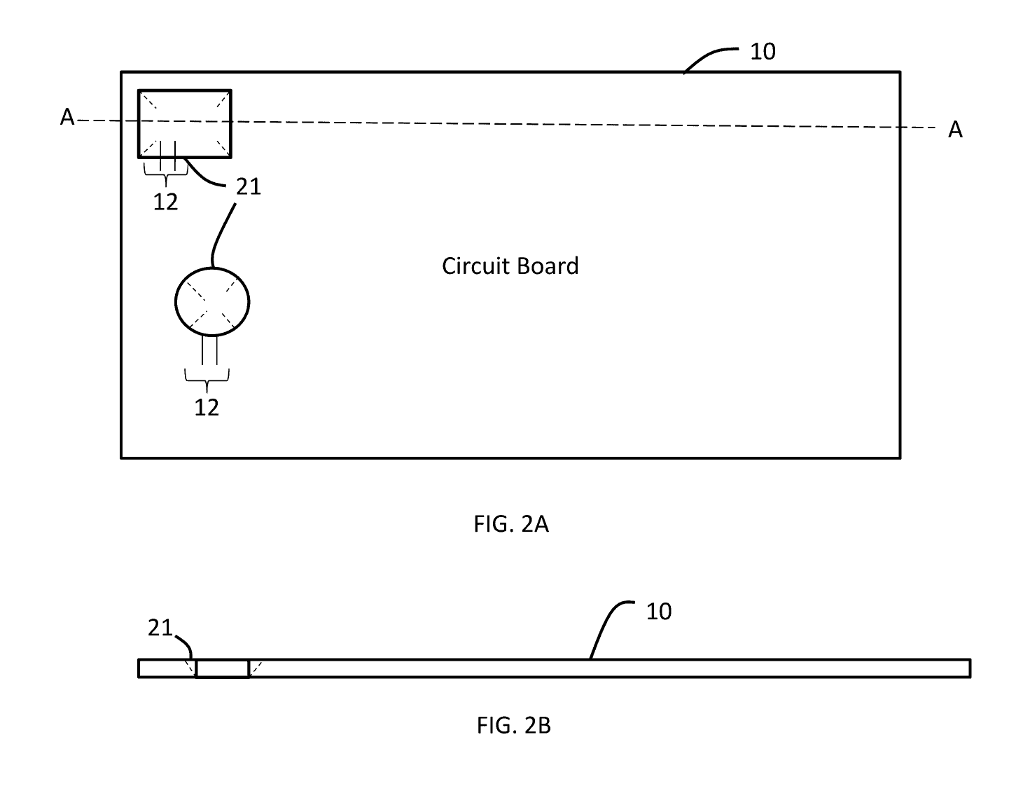

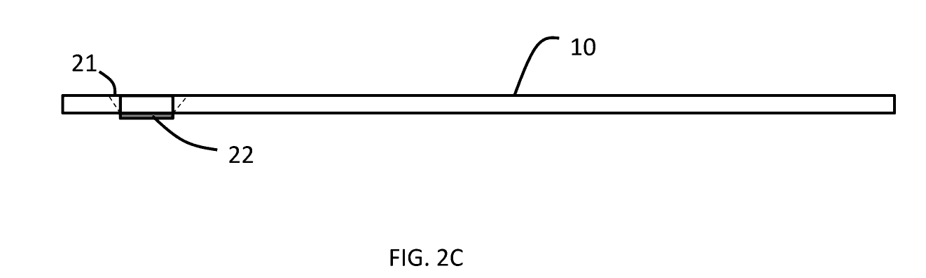

FIGS. 2A, 2B, 2C, 3A, 3B, 4A, 4B, 5A and 5B conceptually show steps in manufacturing a circuit board 10 having a protected oscillator 11, according to various aspects of this disclosure. These also conceptually demonstrate various structures according to aspects of this disclosure.

FIGS. 2A, 2B and 2C show top and two side/cross-sectional views, respectively, of an example of a step in protecting an oscillator 11 in conjunction with a circuit board 10, according to an aspect of this disclosure. In FIGS. 2A and 2B, a hole 21 may be formed in circuit board 10, e.g., but not limited to, by drilling. “Drilling” may be understood as corresponding to any type of drilling, including, for example, but not limited to, drilling using a drill and bit, laser drilling, e-beam drilling, etc. Other methods of creating hole 21 may include, but are not limited to, using any appropriate tool to gouge out an indentation, using an appropriate router, scraping, etc. The shape of hole 21 may be any shape that is convenient and is large enough to fully contain the oscillator 11. Two examples, oblong and circular, are shown for hole 21, but the invention is not thus limited (these two examples are shown in the figures following FIGS. 2A-2C, but this is meant only for the purpose of examples, and the number of holes may depend on the number of oscillators, i.e., there may be one, two, or more, as needed, and FIG. 2A is not intended to be limiting). The hole 21 need not necessarily be formed with straight sides or having the exact dimensions of the oscillator 11 to be embedded in the hole 21. For example, the sides may slant toward a bottom of the hole 21, as shown by the dashed lines in FIGS. 2A and 2B. Hole 21 need not be a through-hole, i.e., it may not be drilled fully through the circuit board 10, but may, rather, have a bottom/lower surface; alternatively, hole 21 may be a through-hole that may be re-sealed with a thermal and electrical insulating material 22, as shown in FIG. 2C, to form a bottom/lower surface (such material may include insulating tape, a fiberglass or ceramic cap/cover/material, etc., and it may be attached to circuit board 10 using techniques similar to techniques described below). Wires/leads 12 may be formed within and/or leading from hole 21, to connect contacts of the oscillator 11 with other portions (components, power, ground, further connections, etc.) of the circuit board 10.

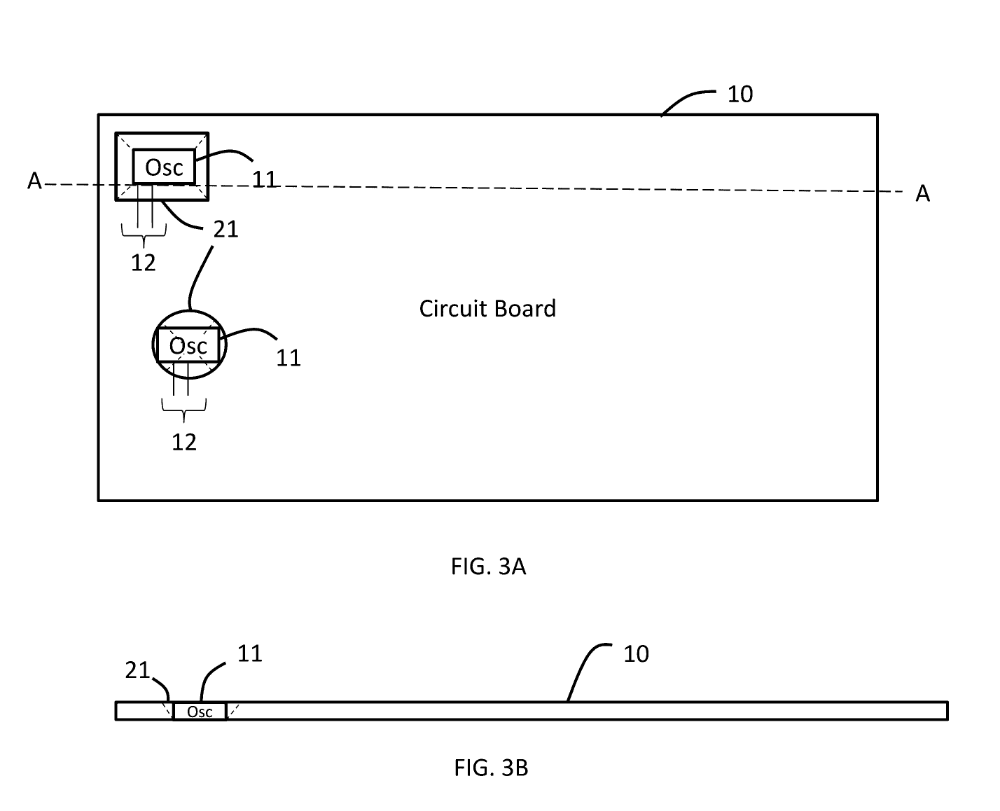

FIGS. 3A and 3B show top and side views, respectively, of an example of a next step in a process of protecting an oscillator 11, according to an aspect of this disclosure. In FIGS. 3A and 3B, the oscillator 11 may be placed/mounted in the hole 21 and may be bonded to leads 12. As shown in FIG. 3B, the oscillator 11 may be fully contained within hole 21, such that the oscillator may not protrude out of the top of hole 21.

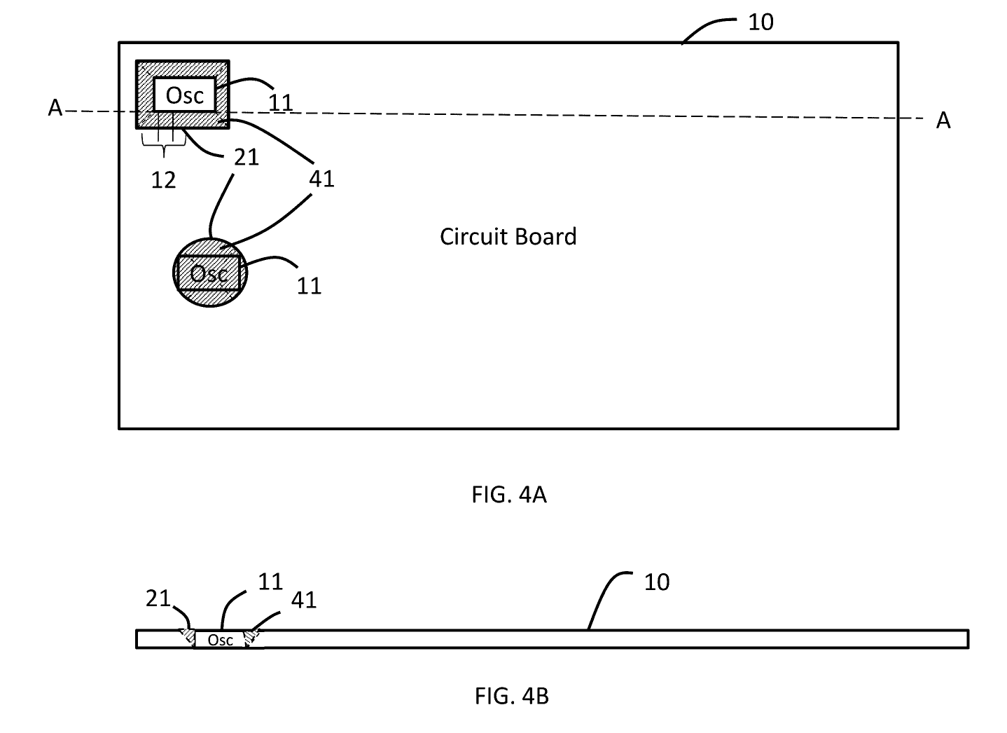

FIGS. 4A and 4B show top and side views, respectively, of an example of an optional further step in protecting an oscillator 11, according to an aspect of this disclosure. In FIGS. 4A and 4B, after oscillator 11 has been placed/mounted within hole 21 in the circuit board 10, a non-heat-conducting sealant/filler 41 may be used to fill unfilled space within hole 21. Hole 21 may be left open on top or may be sealed using the sealant/filler 41, as shown in the two examples of hole 21 in FIG. 4A.

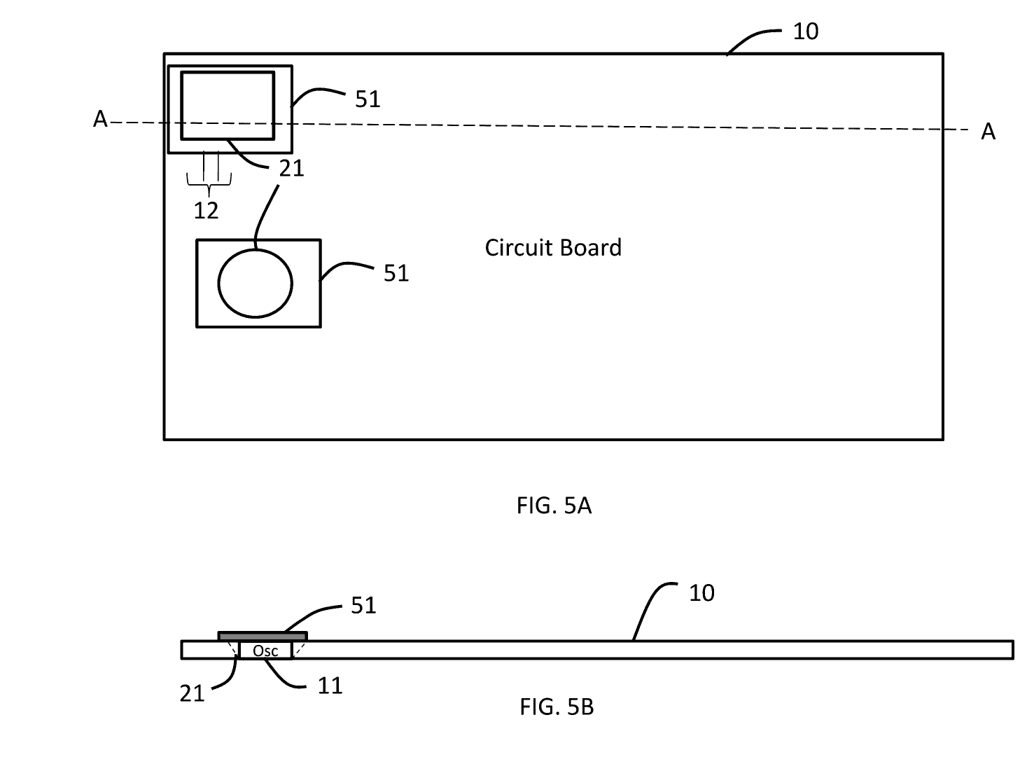

Finally, FIGS. 5A and 5B show top and side views, respectively, of another step in protecting an oscillator 11, according to an aspect of this disclosure. Once the oscillator 11 has been mounted/placed in hole 21, with or without sealant filler, the hole 21 may be sealed using a non-heat-conducting material 51. According to an aspect of this disclosure, that non-heat-conducting material may be tape. Such tape may be, but is not limited to, foam tape, and may have its own adhesive or may adhere over the top of the hole by use of an adhesive, which may be a non-heat-conducting adhesive.

In a variation, in FIGS. 5A and 5B, according to further aspects of this disclosure, the tape 51 may be replaced or augmented by a shielding material or cover (which may also be understood as corresponding to element 51 of FIGS. 5A and 5B), which may be composed of, but which is not limited to, a foam material, a plastic material, a ceramic material, or any other suitable heat-insulating material. The shielding material or cover may be glued or taped on, in or around the hole 21, or may be attached by other suitable means (e.g., mechanical means, such as hooks, that may interlock with holes or indentations in the circuit board 10; etc.). A cover may be designed to be inserted into hole/indentation 21, at least in part, and may be secured by friction, tape, one or more clips, glue, or any other suitable means of securing such a cap.

In either case, as shown in FIG. 5A, the leads 12 may be permitted to penetrate the tape and/or other component(s)/material(s) used to seal hole 21, in order to connect the oscillator 11 with other portions of the circuit board (e.g., power, ground, other components, inputs, outputs, etc.).

In summary, as described above, an oscillator may be protected from air currents, especially convective air currents, and maintained at an approximately constant temperature, by embedding it and sealing it within a circuit board. A hole may be formed in the circuit board. The oscillator may be placed in the hole. Optionally, a sealant/filler may be placed in the hole, if there is unfilled space. And finally, the top of the hole may be sealed with a heat-insulating material.

In contrast with prior methods that may shield an oscillator from air currents, the methods according to the various aspects of this disclosure may generally be simpler and less costly and easier to manufacture. They may generally not require the use of expensive and heat-conducting metals, as in several of the above-described techniques; in fact, aspects of the present disclosure may, rather, be concerned with insulating the oscillator and protecting it from air currents. They may generally not require the use of additional components, in addition to the circuit board, to house the oscillator or to serve as a heat source or heat sink for the oscillator. They may generally not require that the oscillator be capable of being re-positioned, once mounted. The present techniques may also be accomplished in a few simple steps.

Various aspects of the disclosure have been presented above. However, the invention is not intended to be limited to the specific aspects presented above, which have been presented for purposes of illustration. Rather, the invention extends to functional equivalents as would be within the scope of the appended claims. Those skilled in the art, having the benefit of the teachings of this specification, may make numerous modifications without departing from the scope and spirit of the invention in its various aspects.

What is claimed is:

1. A method of mounting an oscillator in a circuit board, the method including:
creating a hole in the circuit board, wherein the hole is of sufficient dimensions to contain the oscillator fully within the hole, without the oscillator protruding out of the hole;
mounting the oscillator in the hole in the circuit board; and
sealing the hole with a heat-insulating material.

2. The method of claim 1, wherein creating the hole in the circuit board comprises drilling the hole in the circuit board.

3. The method of claim 2, wherein said drilling the hole comprises drilling the hole only partially through the circuit board.

4. The method of claim 2, wherein said drilling the hole comprises drilling a through-hole, and wherein the method further includes attaching a heat-insulating material to a lower end of the through-hole to provide a lower surface of the hole.

5. The method of claim 1, further including filling empty space in the hole, after said mounting the oscillator, using a heat-insulating filler or sealant.

6. The method of claim 5, further including using the heat-insulating filler or sealant to seal a top of the hole.

7. The method of claim 1, further including forming electrically-conductive leads configured to electrically connect the oscillator to other portions of the circuit board.

8. The method of claim 7, wherein no heat-conductive material is applied to an interior of the hole, except for the electrically-conductive leads.

9. The method of claim 1, wherein sealing the hole comprises applying insulating tape over a top of the hole.

10. The method of claim 1, wherein sealing the hole comprises applying a cap or cover over a top of the hole.

11. The method of claim 1, wherein no heat source or sink external to the hole is provided to maintain constant temperature within the hole.

12. An apparatus formed by the method according to claim 1.

13. An electronic apparatus comprising:
a non-heat-conductive circuit board;
an oscillator, wherein the oscillator is fully contained in a hole in the oscillator, without protrusion of the oscillator outside the hole;
one or more electrically-conductive leads configured to connect the oscillator with other portions of the circuit board; and
a heat-insulating covering configured to seal the oscillator within the hole, except for allowing the electrically-conductive leads to penetrate the heat-insulating covering.

14. The electronic apparatus of claim 13, wherein the heat-insulating covering comprises insulating tape.

15. The electronic apparatus of claim 13, further comprising a heat-insulating filler or sealant material applied in the hole to fill empty space in the hole.

16. The electronic apparatus of claim 16, wherein the filler or sealant material is configured to seal the oscillator in the hole, except for allowing the electrically-conducting leads to penetrate.
